(19) United States
(12) Patent Application Publication
(10) Pub. No.: US 2026/0229156 A1
(43) Pub. Date: Aug. 6, 2026

(54) MICRO-LED SYSTEMS HAVING IN SITU CURRENT MEASUREMENT CIRCUITS

(71) Applicant: Microsoft Technology Licensing, LLC, Redmond, WA (US)

(72) Inventors: Lawrence A. PRATHER, Boulder Creek, CA (US); Kenneth Colin DYER, Pleasonton, CA (US); Barry THOMPSON, Menlo Park, CA (US)

(21) Appl. No.: 19/042,899

(22) Filed: Jan. 31, 2025

(51) Int. Cl. G09G 3/00; G01R 31/26

(52) U.S. Cl. CPC G09G 3/006; G01R 31/2635; G09G 2300/0838; G09G 2330/12

(57) ABSTRACT

Microscopic light emitting diodes (micro-LEDs) systems having in situ current measurement circuits are described. An example micro-LED system includes a set of micro-LEDs formed in a display substrate and a set of pixel driver circuits formed in a backplane substrate, coupled to the display substrate, where a respective pixel driver circuit is to provide current to a respective micro-LED during a first mode of operation for the set of micro-LEDs. The micro-LED system further includes a current measurement circuit, formed in the backplane substrate, comprising an operational amplifier configured to drive a source-follower transistor. The micro-LED system further includes a set of pass transistors to, on a per pixel driver circuit basis, selectively redirect current from one or more of the set of pixel driver circuits to the current measurement circuit allowing for in situ measurement of the redirected current within the backplane substrate.

### BACKGROUND

Microscopic light emitting diodes (micro-LEDs) are typically formed on a display substrate separate from a backplane substrate, which includes the pixel driver circuits for driving the micro-LEDs. The backplane substrate also includes other circuits, including control circuits. The display substrate, having the micro-LED arrays, is formed using different process technologies from the ones used to form the backplane substrate. In addition, micro-LEDs require different voltages, including negative voltages, to operate them. As an example, in a cathode-connected micro-LED array, the common cathode for the micro-LEDs is maintained at a negative voltage relative to the anode terminals for the micro-LEDs. The negative voltage at the common-cathode terminal can be as low as negative 5 volts, or even lower. Such voltages can damage the low voltage transistors formed on the backplane substrate. In addition, micro-LEDs require different analog voltages to operate, which are also ordinarily incompatible with the low voltage transistors formed on the backplane substrate. In addition, the voltage swing on the micro-LED side is higher than the voltage swing on the circuits formed on the backplane substrate. This means that it is difficult to measure current and voltages associated with the micro-LEDs.

Prior solutions for addressing such issues are inadequate. Accordingly, there is a need for improvements to the current measurement circuits for use with micro-LEDs.

### SUMMARY

In one example, the present disclosure relates to a micro-LED system including a set of micro-LEDs formed in a display substrate. The micro-LED system may further include a set of pixel driver circuits formed in a backplane substrate coupled to the display substrate, where a respective pixel driver circuit is to provide current to a respective micro-LED during a first mode of operation for the set of micro-LEDs.

The micro-LED system may further include a current measurement circuit, formed in the backplane substrate, comprising an operational amplifier configured to drive a source-follower transistor. The micro-LED system may further include a set of pass transistors to, during a second mode of operation, different from the first mode of operation, on a per pixel driver circuit basis, selectively redirect current from one or more of the set of pixel driver circuits to the current measurement circuit allowing for in situ measurement of the redirected current within the backplane substrate.

In another example, the present disclosure relates to a method for in situ measurement of current associated with one or more micro-LEDs in a micro-LED system. The micro-LED system may include: (1) a set of micro-LEDs formed in a display substrate, and (2) a set of pixel driver circuits formed in a backplane substrate coupled to the display substrate, where each of the set of pixel driver circuits is to provide current to a respective one of the set of micro-LEDs during a normal mode of operation for the set of micro-LEDs.

The method may include using a set of pass transistors, during a test mode of operation, on a per pixel driver circuit basis, redirecting current from one or more of the set of pixel driver circuits to a current measurement circuit. The method may further include using the current measurement circuit performing an in situ measurement of the redirected current within the backplane substrate, where the current measurement circuit comprises an operational amplifier configured to drive a source-follower transistor.

In yet another example, the present disclosure relates to a micro-LED system comprising a set of micro-LEDs formed in a display substrate. The micro-LED system may further include a set of pixel driver circuits formed in a backplane substrate coupled to the display substrate, where a respective pixel driver circuit is to provide current to a respective micro-LED during a first mode of operation for the set of micro-LEDs.

The micro-LED system may further include a set of pass transistors to, during a second mode of operation, different from the first mode of operation, on a per pixel driver circuit basis, selectively redirect current from one or more of the set of pixel driver circuits to a current measurement circuit, formed in the backplane substrate, allowing for in situ measurement of the redirected current within the backplane substrate. The current measurement circuit may comprise: (1) an operational amplifier configured to drive a source-follower transistor, (2) a level translation and scaling circuit coupled to the source-follower transistor, and (3) an analog to digital converter (ADC) coupled to the level translation and scaling circuit, where the level translation and scaling circuit is configured to scale voltage levels for coupling with the ADC.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

The present disclosure is illustrated by way of example and is not limited by the accompanying figures, in which like references indicate similar elements. Elements in the figures are illustrated for simplicity and clarity and have not necessarily been drawn to scale.

FIG. 1 shows a micro-LED-based display apparatus with a display substrate, including micro-LEDs, coupled with a backplane substrate, including pixel driver and current measurement circuits in accordance with one example;

FIG. 2 is a block diagram of a micro-LED system including a current pixel driver circuit and a current measurement circuit in accordance with one example;

FIG. 3 shows a micro-LED current measurement system with an ability to null leakage current during current measurement by the current measurement circuit;

FIG. 4 shows an example current measurement circuit with one implementation of the level translation and scaling circuit of FIG. 2;

FIG. 5 shows a current measurement circuit with an improved level translation and scaling circuit in accordance with one example;

FIG. 6 shows a current measurement circuit with an improved level translation and scaling circuit in accordance with one example;

FIG. 7 shows a current measurement circuit with an improved level translation and scaling circuit in accordance with one example;

FIG. 8 shows a current measurement circuit with an improved level translation and scaling circuit in accordance with one example;

FIG. 9 shows a current measurement circuit with an improved level translation and scaling circuit in accordance with one example; and

FIG. 10 shows a flow chart of an example method for in situ measurement of the current associated with one or more micro-LEDs in a micro-LED system.

### DETAILED DESCRIPTION

Examples disclosed in the present disclosure relate to microscopic light emitting diodes (micro-LEDs) systems having in situ current measurement circuits. As noted earlier, micro-LEDs are typically formed on a display substrate separate from a backplane substrate, which includes the pixel driver circuits for driving the micro-LEDs. The backplane substrate also includes other circuits, including control circuits. The display substrate, having the micro-LED arrays, is formed using different process technologies from the ones used to form the backplane substrate. In addition, micro-LEDs require different voltages, including negative voltages, to operate them. As an example, in a cathode-connected micro-LED array, the common cathode for the micro-LEDs is maintained at a negative voltage relative to the anode terminals for the micro-LEDs. The negative voltage at the common-cathode terminal can be as low as negative 5 volts, or even lower. Such high voltages can damage the low voltage transistors formed on the backplane substrate. In addition, micro-LEDs require different analog voltages to operate, which are also ordinarily incompatible with the low voltage transistors formed on the backplane substrate. In addition, the voltage swing on the micro-LED side is higher than the voltage swing on the circuits formed on the backplane substrate. This means that it is difficult to measure current and voltages associated with the micro-LEDs. Prior solutions for addressing such issues are inadequate. Accordingly, there is a need for improvements to the current measurement circuits for use with micro-LEDs.

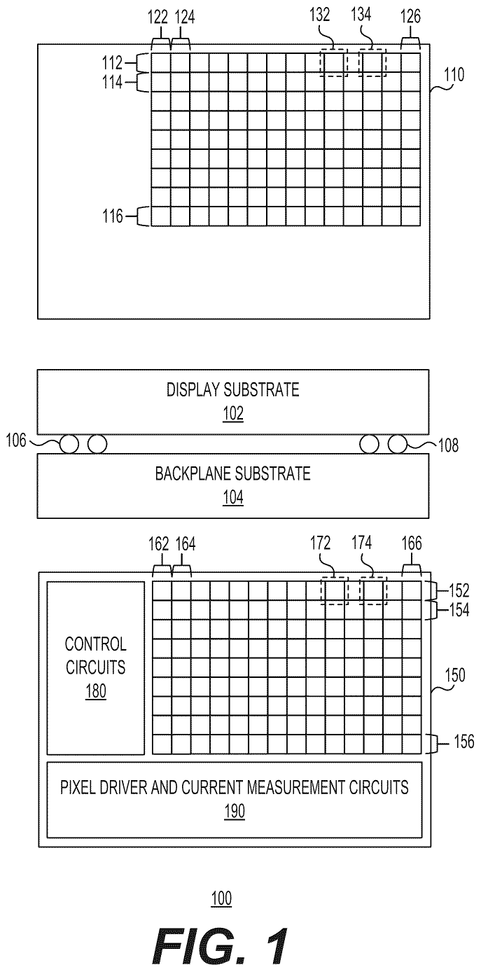

FIG. 1 shows a micro-LED-based display apparatus 100 with a display substrate 102, including micro-LEDs, coupled with a backplane substrate 104, including pixel driver and current measurement circuits in accordance with one example. In this example, display substrate 102 is shown as bonded with backplane substrate 104 using micro-bumps 106 and 108. Other types of process technologies, including ball grid arrays or through silicon vias, may also be used. As shown in view 110 of display substrate 102, the display substrate 102 includes a micro-LED array with micro-LEDs (e.g., micro-LEDs 132 and 134) organized in rows (e.g., rows 112, 114, and 116) and columns (e.g., columns 122, 124, and 126). As shown in view 150 of backplane substrate 104, the backplane substrate 104 includes an array of pixel hardware blocks (e.g., pixel hardware blocks 172 and 174) that are also organized in rows (e.g., rows 152, 154, and 156) and columns (e.g., columns 162, 164, and 166). The pixel hardware blocks are pitch-matched to the anode and cathode terminals of the micro-LEDs included in the display substrate 102. In addition, in this example, each of the pixel hardware blocks, formed as part of backplane substrate 104, have the same footprint as each of the micro-LEDs formed as part of display substrate 102. Each of the micro-LEDs included in display substrate 102 is configured to emit light in response to current received from respective pixel driver circuits (e.g., included within pixel hardware blocks 172 and 174) located on the backplane substrate 104.

With continued reference to FIG. 1, backplane substrate 104 further includes control circuits 180 and pixel driver and current measurement circuits 190. Control circuits 180 include circuits, including registers, finite state machines (or other control logic), programmable digital to analog converters (DACs), voltage regulators, and other circuits to operate the micro-LEDs. Registers and other aspects included in the control circuits 180 can interface with pixel driver and current measurement circuits 190 to allow for the initiation of measurements or sensing of micro-LEDs. Pixel driver and current measurement circuits 190 include pixel driver circuits and current measurement circuits described later. Although FIG. 1 shows micro-LED-based display apparatus 100 as having certain components that are arranged in a certain manner, micro-LED-based display apparatus 100 may include additional or fewer components that are arranged differently.

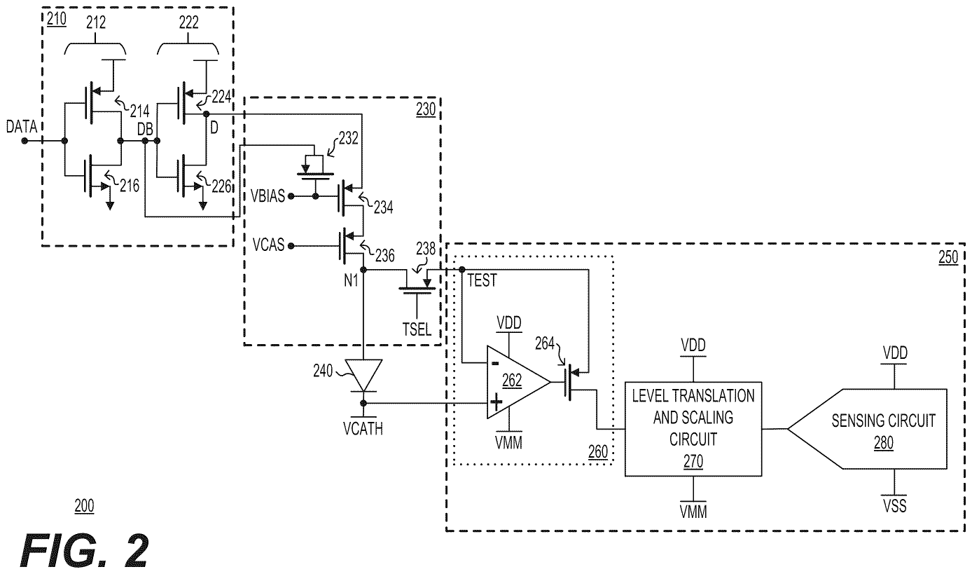

FIG. 2 is a block diagram of a micro-LED system 200 including a pixel driver circuit 230 and a current measurement circuit 250 in accordance with one example. The micro-LED system 200 includes an input stage 210, a pixel driver circuit 230, and a current measurement circuit 250. Input stage 210 is configured to receive data, via node DATA, corresponding to a respective pixel. Input stage 210 comprises inverters 212 and 222. Inverter 212 is formed using a PMOS transistor 214 and an NMOS transistor 216. Inverter 222 is formed using a PMOS transistor 224 and an NMOS transistor 226. The input stage 210 provides two values for the data. One is a non-inverted value at node D and the second one is an inverted value at node DB. Pixel driver circuit 230 is configured to receive both the inverted value and the non-inverted value output by the input stage 210. Pixel driver circuit 230 is coupled to a micro-LED 240, such that the pixel driver circuit 230 can provide a current to drive the micro-LED 240.

Pixel driver circuit 230 comprises a transistor 232, which is configured to receive the value output at node DB of the input stage 210. The gate of transistor 232 is configured to receive a bias voltage at the node VBIAS. Pixel driver circuit 230 further comprises a PMOS transistor 234 coupled in series with another PMOS transistor 236. PMOS transistor 234 is coupled to receive the non-inverted value from node D of input stage 210. The gate of PMOS transistor 236 is coupled to receive another bias voltage via node VCAS. Pixel driver circuit 230 further includes another PMOS transistor 238, which is coupled to the node labeled TEST. The node TEST can be coupled, via node N1, to the anode of micro-LED 240. The gate of PMOS transistor 238 is coupled to receive a select signal via the node TSEL, allowing PMOS transistor 238 to couple any signal received via the node TEST to the anode of micro-LED 240. The select signal—TSEL—can be used to select an individual micro-LED pixel driver circuit (e.g., by column and row) or in combination with other micro-LEDs' pixel driver circuits. The anode of micro-LED 240 is coupled at node N1 to both a terminal of PMOS transistor 236 and PMOS transistor 238.

With continued reference to FIG. 2, in terms of the operation of the pixel driver circuit 230, during normal operation of the micro-LED 240, current flows from PMOS transistor 234 and PMOS transistor 236 into the anode of micro-LED 240 via node N1. This is because during the normal mode of operation, PMOS transistor 238 is turned off by asserting a logic high value at the TSEL node. To accomplish an in situ method to measure the current coming from the pixel driver circuit 230, the anode and cathode of the micro-LED 240 need to be forced to the same voltage while the current measurement circuit sinks all the current from PMOS transistors 234 and 236. To enable current measurement, PMOS transistor 238 is turned on (by asserting the TSEL signal on a per-pixel or per micro-LED basis) and the TEST node is forced to have the same voltage potential as the VCATH node. This will cause the micro-LED 240 to cease conducting current so that the current flowing along the path including the PMOS transistor 234 and PMOS transistor 236 into the anode of micro-LED 240 via node N1 is diverted to the current measurement circuit 250. Current measurement circuit 250 includes a circuit combination 260 of an operational amplifier 262 and a source-follower, which is implemented as a PMOS transistor 264.

The circuit combination 260 of operational amplifier 262 and PMOS transistor 264 force the TEST node to be at the same potential as the voltage at the VCATH node (e.g., the common-cathode voltage for the micro-LED array). The circuit combination 260 of operational amplifier 262 and PMOS transistor 264 is coupled via the drain of PMOS transistor 264 to a level translation and scaling circuit 270. The level translation and scaling circuit 270 is coupled to a sensing circuit 280, which can be implemented using an analog to digital converter (ADC). As shown in FIG. 2, each of circuit combination 260, level translation and scaling circuit 270, and sensing circuit 280 is configured to receive the VDD voltage supply and the VMM voltage supply (indicated by namesake voltage terminals in FIG. 2). The VMM voltage supply is a fixed value, which is less than or equal to the common-cathode voltage (at the VCATH voltage terminal). Often, these voltages are negative voltages but that is not a necessary condition for the measurements being performed using current measurement circuit 250.

During testing, there are five possible cases that need to be detected: normal function, open pixel driver, shorted pixel driver, open micro-LED, and shorted micro-LED. This requires two measurement types: current and voltage at the anode of the micro-LED 240, labeled as node N1 in FIG. 2. Table 1 below shows the five possible cases and the measured current and measured voltage for each of the five cases.

TABLE 1

| Case | Measured Current | Measured Voltage |
|---|---|---|
| Normal Function | Expected Range | Expected Range |
| Open Pixel Driver | Lower Than | Near the Cathode (VCATH) |
| | Expected | Voltage |
| Shorted Pixel Driver | Higher Than | Near the Supply Voltage |
| | Expected | (VDD) |
| Open Micro-LED | Expected Range | Near the Supply Voltage |
| | | (VDD) |
| Shorted Micro-LED | Lower Than | Near the Cathode (VCATH) |
| | Expected | Voltage |

To distinguish between the open pixel driver and shorted micro-LED cases, a known current would have to be sourced through PMOS transistor 238 into the micro-LED 240 and then the voltage is measured. If the measured voltage rises to the expected range, then the pixel driver is open, else the micro-LED is shorted. This can be realized by connecting a current-mode digital to analog converter (DAC) to the TEST node. Although FIG. 2 shows micro-LED system 200 as having certain components that are arranged in a certain manner, micro-LED system 200 may include additional or fewer components that are arranged differently.

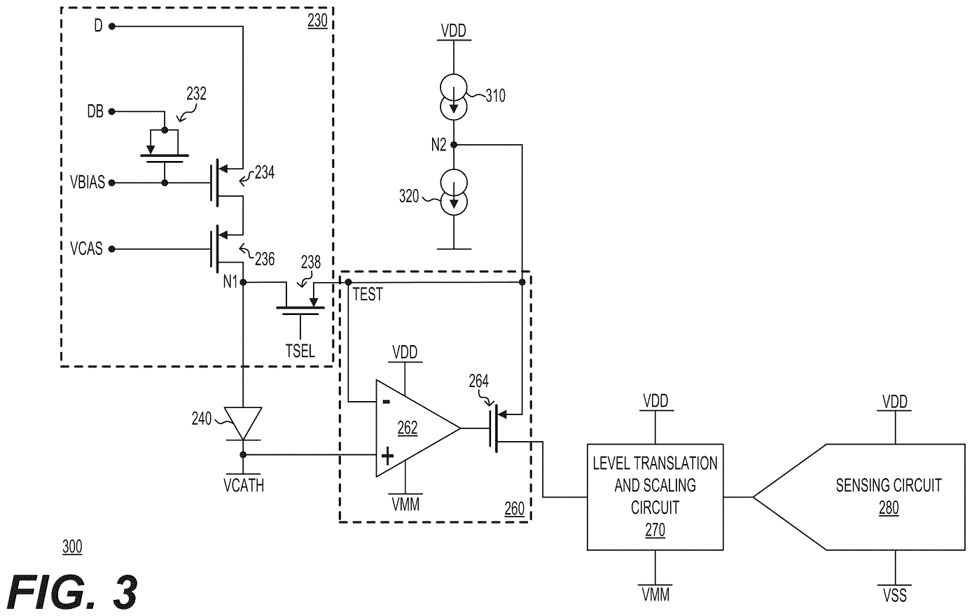

FIG. 3 shows a micro-LED current measurement system 300 with an ability to null leakage current during current measurement by the current measurement circuit. Unless expressly indicated otherwise, the same or similar circuits and components that are shown in FIG. 3 are referred to using the same or similar reference numbers as used in FIG. 2. As a result, such same or similar circuits and components are not described again as part of the description associated with FIG. 3. During current measurement, the accuracy of measured current can be affected because of leakage currents. Current can be added or subtracted from the TEST node to cancel the effect of any leakage current from the measurement for one or more micro-LEDs. As an example, this is accomplished by adding adjustable source or sink currents via current source 310 and current sink 320. In one example, each of current source 310 and current sink 320 can be implemented as current-mode digital-to-analog converters (DACs).

The amount of current being sourced or sinked can be determined by turning off the pixel driver circuit (e.g., pixel driver circuit 230) and then adjusting the current-mode DACs to zero-out the remaining leakage currents as measured using sensing circuit 280. Although FIG. 3 shows micro-LED current measurement system 300 as having certain components that are arranged in a certain manner, micro-LED current measurement system 300 may include additional or fewer components that are arranged differently.

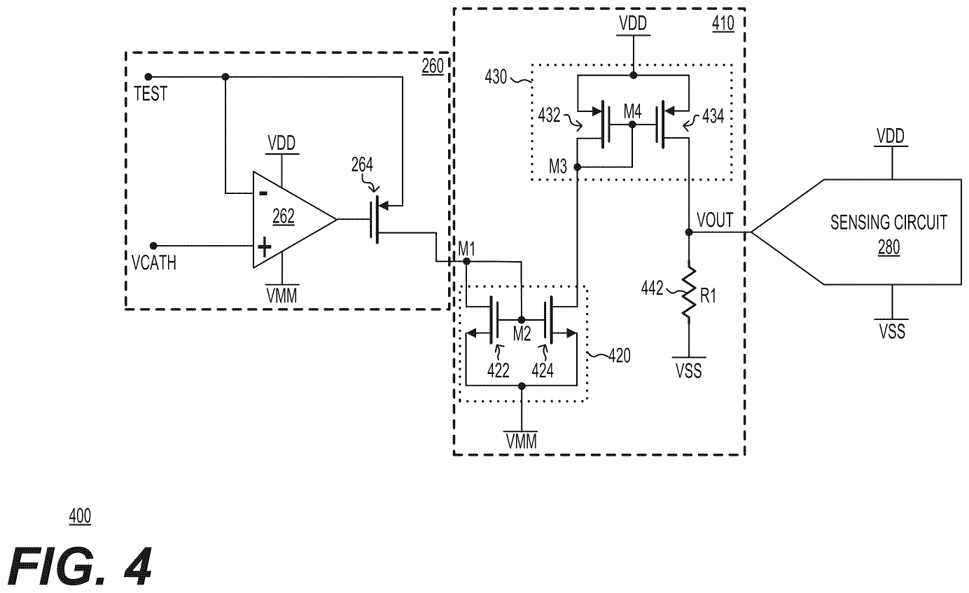

FIG. 4 shows an example current measurement circuit 400 with one implementation of the level translation and scaling circuit 270 of FIG. 2. Unless expressly indicated otherwise, the same or similar circuits and components that are shown in FIG. 4 are referred to using the same or similar reference numbers as used in FIG. 2 or FIG. 3. As a result, such same or similar circuits and components are not described again as part of the description associated with FIG. 4. In this example, the level translation and scaling circuit 410 can be realized with two current mirrors 420 and 430 and a resistor R1 442 producing a single-ended output to sensing circuit 280. Current mirror 420 is coupled via node M1 to the TEST node. This way, the level translation and scaling circuit 410 can receive the current from the TEST node. Current mirror 420 includes NMOS transistor 422 with one terminal coupled to the node M1 and another terminal coupled to the VMM terminal for receiving the VMM voltage. The gate of NMOS transistor 422 is coupled with node M2 and the gate of another NMOS transistor 424. One terminal of NMOS transistor 424 is coupled to the VMM voltage terminal and the other terminal is coupled to the node M3. Current mirror 430 includes PMOS transistor 432 and another PMOS transistor 434. One terminal of PMOS transistor 432 and one terminal of PMOS transistor 434 is coupled to the VDD terminal for receiving the VDD voltage. The gates of PMOS transistors 432 and 434 are tied via node M4, which is further coupled to node M3. One terminal of PMOS transistor 434 is coupled to the VOUT terminal, which is coupled to one terminal of resistor R1 442. The other terminal of resistor R1 442 is grounded via the VSS terminal.

With continued reference to FIG. 4, scaling in the current domain can be done by adjusting the width (W) or the length (L) of the two NMOS transistors (422 and 424), of the two PMOS transistors (432 and 434) or of both the NMOS transistors and the PMOS transistors. Resistor R1 442 translates the current into a voltage at the VOUT node, which is coupled to the input of sensing circuit 280. The value of resistor R1 442 can also be scaled to increase or decrease the sensitivity of the current measurement. The scaling of input current (I) to the output voltage (VOUT) at the VOUT terminal can be expressed by the following equation:

$$VOUT = I * ( p / q ) * ( n / m ) * R 1 , where p / q = {( W / L )}_{NMOS 424} / {( W / L )}_{NMOS 422}$$

$$and n / m = {( W / L )}_{NMOS 434} / {( W / L )}_{NMOS 432} .$$

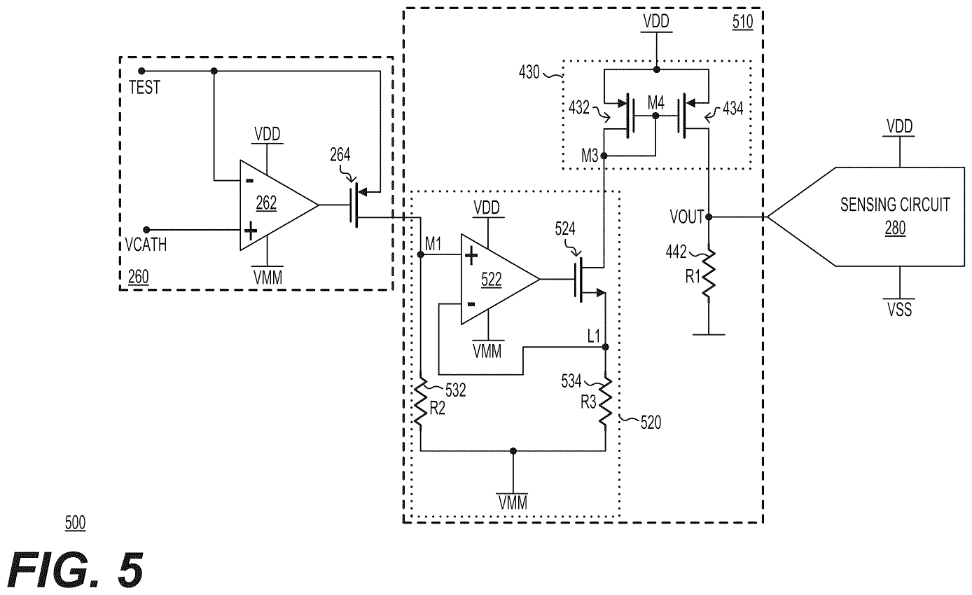

While the level translation and scaling circuit 410 performs the level translation and scaling function, it has a few limitations. First, the common-mode input voltage is limited by the gate to source voltage (V_{GS}) of NMOS transistor 422, reducing the drain to source voltage (V_{DS}) of PMOS transistor 264. Diode-connected NMOS transistor 422 acts a voltage-controlled resistor, and the voltage drop across it (V_{GS}) puts pressure on the drain to source voltage (V_{DS}) of PMOS transistor 264, requiring it to be as small as possible. This is because a larger drain to source voltage (V_{DS}) of PMOS transistor 264 limits the range of the common-mode input voltage. Second, the stability of operational amplifier 262 is degraded at low input current due to the non-dominant pole moving to lower frequency as the current is reduced, lowering the phase margin. Third, there is a limited positive voltage swing due to the VD_{Sat} requirement for the PMOS transistor 434. Fourth, there is poor power supply rejection due to non-cascoded current sources and a single ended output. As explained with respect to FIG. 5, the common-mode input voltage range of the level translation and scaling circuit 410 can be improved. Although FIG. 4 shows current measurement circuit 400 as having certain components that are arranged in a certain manner, current measurement circuit 400 may include additional or fewer components that are arranged differently. As an example, although FIG. 4 shows resistor R1 442 coupled to the VOUT node, this resistor could be omitted, such that sensing circuit 280 can measure the current output by the level translation and scaling circuit 410 using a current-measuring analog to digital converter (ADC).

FIG. 5 shows an example current measurement circuit 500 with an improved level translation and scaling circuit 510. The improvement relates to eliminating current mirror 420 of FIG. 4 and replacing it with a current repeater circuit 520 of FIG. 5. Unless expressly indicated otherwise, the same or similar circuits and components that are shown in FIG. 5 are referred to using the same or similar reference numbers as used in FIG. 2, FIG. 3, or FIG. 4. As a result, such same or similar circuits and components are not described again as part of the description associated with FIG. 5. Current repeater circuit 520 comprises an operational amplifier 522, an NMOS transistor 524, a resistor R2 532, and another resistor R3 534. One input of operational amplifier 522 is coupled to node M1 and the other input is coupled to node L1. NMOS transistor 524 is coupled between the node L1 and node M3. Resistor R2 532 is coupled between the node M1 and the voltage terminal VMM. Resistor R3 534 is coupled between the node L1 and the voltage terminal VMM.

The value of the resistor R2 532 is selected to ensure that the voltage drop across it is no more than a few hundred millivolts even at the maximum current being measured. This way PMOS transistor 264 can continue to conduct current even when the gate of PMOS transistor 264 is equal to the voltage being received via the VMM terminal. As a result, the input common-mode voltage range in the negative direction is limited only by the gate to source voltage (V_{GS}) of the PMOS transistor 264, and is no longer affected by its drain to source (V_{DS}) voltage. Although FIG. 5 shows current measurement circuit 500 as having certain components that are arranged in a certain manner, current measurement circuit 500 may include additional or fewer components that are arranged differently.

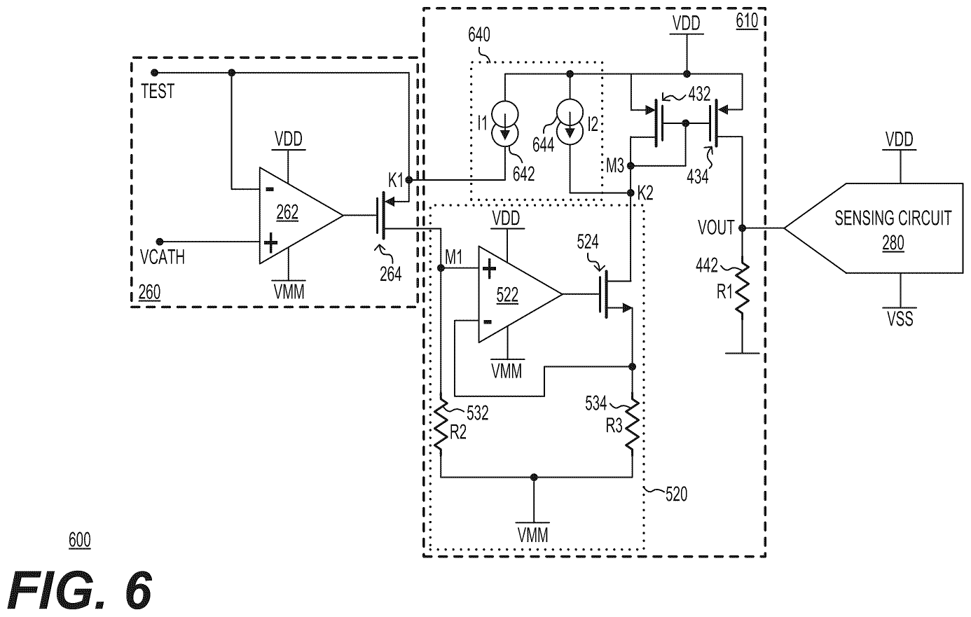

FIG. 6 shows an example current measurement circuit 600 with an improved level translation and scaling circuit 610. The improvement relates to adding pedestal current I1 and current I2 via current source circuit 640. The pedestal current I1 prevents the test current from going to zero, resulting in certain advantages as described further below. Unless expressly indicated otherwise, the same or similar circuits and components that are shown in FIG. 6 are referred to using the same or similar reference numbers as used in FIG. 2, FIG. 3, FIG. 4, or FIG. 5. As a result, such same or similar circuits and components are not described again as part of the description associated with FIG. 6. The stability of operational amplifier 262 is improved by adding the pedestal current I1 (current source 642), through PMOS transistor 264, via node K1. The amount of I1 current is selected to a large enough fraction of the maximum current to be measured.

As an example, if the current to be measured varies between 100 nA and 100 uA, three orders of magnitude, the transconductance (gm) of non-dominant pole changes as the square-root of that, approximately 32 to 1. The addition of the pedestal current I1 changes this ratio. As an example, if one were to add 50 uA as the pedestal current, then the current flowing through PMOS transistor 264 varies from a minimum of approximately 50 uA to a maximum of approximately 150 uA maximum, which is only a factor of three. As a result the transconductance (gm) of the non-dominant pole, in turn, varies by the square-root of 3, or about 1.7 to 1. This limits the movement of the non-dominant pole, making the frequency compensation of operational amplifier 262 more manageable.

With continued reference to FIG. 6, the current amount 12 (from current source 644) is subtracted from the output of the current mirror such that the current amount I1 that is added, and mirrored, is cancelled. The current amounts I1 and 12 are equal if the mirrored current is a one-to-one ratio; however, if the mirror is a different ratio, then the current amount 12 can be scaled accordingly such that the effect of the pedestal current I1 is cancelled at the drain of NMOS transistor 524, which is coupled to node K2 and node M3. Although FIG. 6 shows current measurement system 600 as having certain components that are arranged in a certain manner, current measurement system 600 may include additional or fewer components that are arranged differently.

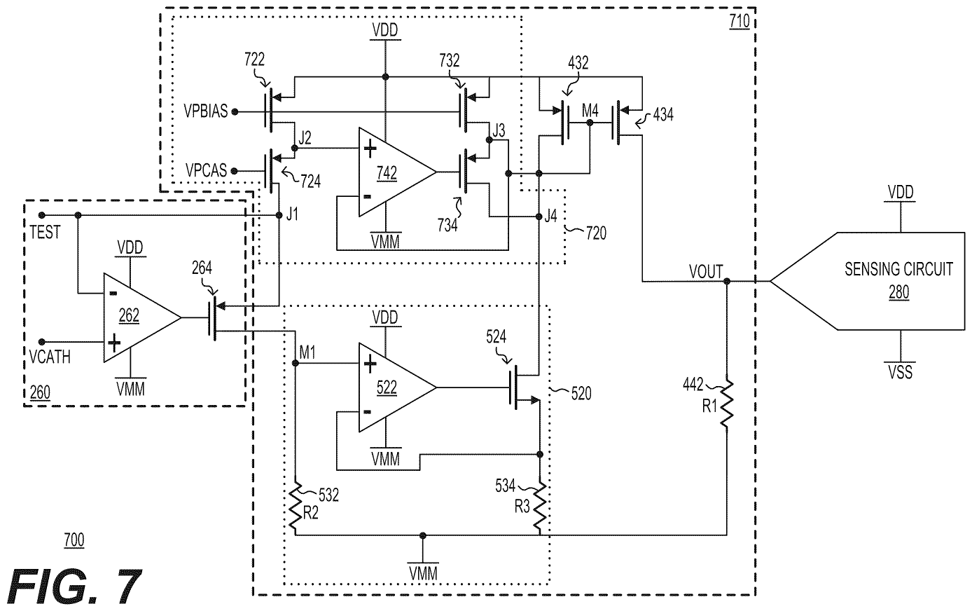

FIG. 7 shows a current measurement circuit 700 with an improved level translation and scaling circuit 710 in accordance with one example. The improvement relates to an implementation of a pedestal current circuit 720 for providing pedestal current I1 and current I2 in a manner that results in better matching of the current I2 with the current I1. Unless expressly indicated otherwise, the same or similar circuits and components that are shown in FIG. 7 are referred to using the same or similar reference numbers as used in FIG. 2, FIG. 3, FIG. 4, FIG. 5, or FIG. 6. As a result, such same or similar circuits and components are not described again as part of the description associated with FIG. 7. As explained with respect to FIG. 6, the pedestal current I1 prevents the test current from going to zero. However, as described with respect to FIG. 6, the current amount 12 needs to be subtracted from the output of the current mirror such that the current amount I1 that is added, and mirrored, is cancelled. The input common-mode voltage range can be swept between the voltages applied to the voltage terminals VDD and VMM, making the implementation for the pedestal current I1 and the pedestal current subtraction 12 challenging. As an example, the differences in the drain to source voltages of certain transistors in the current mirrors can cause issues with such current subtraction. To mitigate this impact, a gain-boosted cascode circuit 720 is implemented as part of the level translation and scaling circuit 710.

With continued reference to FIG. 7, the gain-boosted cascode circuit 720 includes another operational amplifier 742 added to the current mirrors. The gain-boosted cascode circuit 720 includes PMOS transistor 722 coupled between the VDD voltage terminal and node J2. Another PMOS transistor 724 is coupled between the node J2 and node J1. The gain-boosted cascode circuit 720 further includes PMOS transistor 732 coupled between the VDD voltage terminal and node J3. Another PMOS transistor 734 is coupled between the node J3 and node J4. Operational amplifier 742 is arranged to drive the gate of PMOS transistor 734 in a closed loop. As part of the gain-boosted cascode circuit 720, the operational amplifier 742 copies the drain to source voltage (V_{DS}) of the PMOS transistor 722, and forces the drain to source voltage (V_{DS}) of the PMOS transistor 732 to match it, keeping the currents constant regardless of the voltage differences at the drains of PMOS transistors 724 and 734, respectively. This remains the case even when the PMOS transistor 724 is forced from the saturation region into the triode region by the voltage being applied to the TEST node. In sum, the use of operational amplifier 742 as part of the level translation and scaling circuit 710 allows one to match the currents I1 and 12, as described earlier with respect to FIG. 6. Although FIG. 7 shows current measurement circuit 700 as having certain components that are arranged in a certain manner, current measurement circuit 700 may include additional or fewer components that are arranged differently.

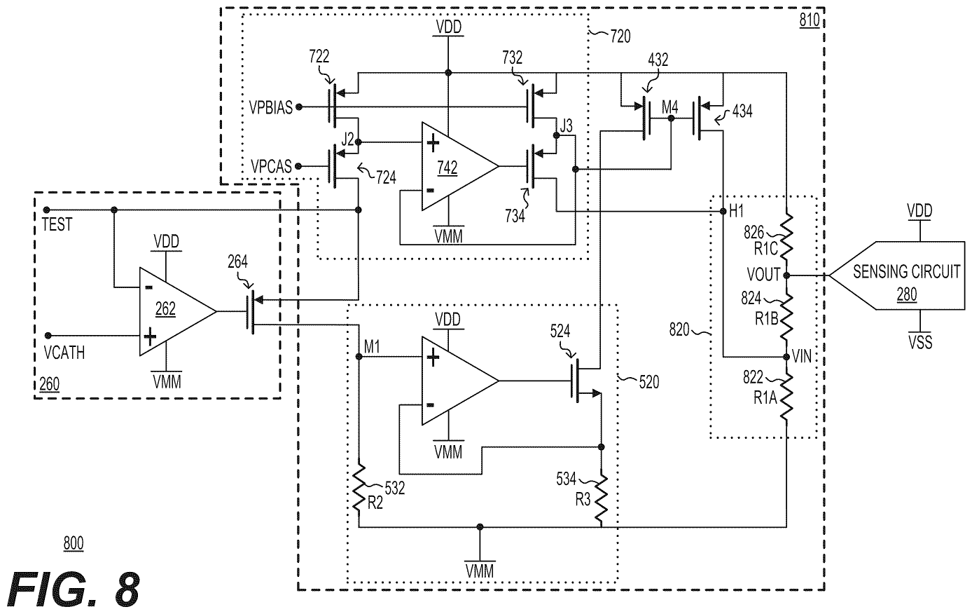

FIG. 8 shows a current measurement circuit 800 with an improved level translation and scaling circuit 810 in accordance with one example. The improvement relates to the use of a resistor string 820 to improve the positive voltage swing limited due to the requirement for keeping the drain to source voltage (V_{DS}) of the PMOS transistor 434. Unless expressly indicated otherwise, the same or similar circuits and components that are shown in FIG. 8 are referred to using the same or similar reference numbers as used in FIG. 2, FIG. 3, FIG. 4, FIG. 5, FIG. 6, or FIG. 7. As a result, such same or similar circuits and components are not described again as part of the description associated with FIG. 8. Resistor string 820 includes a resistor R1A 822 coupled between the VIN voltage terminal and the VMM voltage terminal. Resistor string 820 further includes a resistor R1B coupled between the VIN voltage terminal and the VOUT voltage terminal, which is coupled with the sensing circuit 280. Resistor string 820 further includes a resistor R1C 826 coupled between the VDD voltage terminal and the VOUT voltage terminal. Instead of terminating a single resistor (e.g., resistor R1 442 of FIG. 7) to the VSS ground voltage terminal, the resistor string 820 is terminated to the VMM voltage terminal, which has a more negative voltage (VMM) coupled to it than the ground voltage. Moreover, in this way, the voltages at the VOUT voltage terminal (VOUT) and at the VIN voltage terminal (VIN) are decoupled.

The VOUT voltage at the VOUT voltage terminal and the VIN voltage at the VIN voltage terminal can be expressed by the equations shown in Table 2 below. The common-mode voltages in the table below correspond to a condition in which the drain to source current (I_{DS PMOS 434}) flowing through the PMOS transistor 434 is zero.

TABLE 2

Total resistance (RT) = R1A + R1B + R1C
Common-mode input voltage (VIN_CM) =
((VDD − VMM) * R1A/RT) + VMM
Input swing voltage (VIN_SWING) =
I_{DS PMOS 434} * (R1A * (R1B + R1C))/RT
Common-mode output voltage (VOUT_CM) =
((VDD − VMM) * (R1A + R1B)/RT)) + VMM
Output swing voltage (VOUT_SWING) =
I_{DS PMOS 434} * (R1A * R1C)/RT

Advantageously, by appropriately selecting the resistance values for resistors R1A, R1B, and R1C, the input voltage (VIN) and the output voltage (VOUT) can both be independently adjusted to provide a linear rail-to-rail (VSS to VDD) input to the sensing circuit 280 while at the same time keeping the drain to source voltage (V_{DS}) of the PMOS transistor 434 in the saturation region. Although FIG. 8 shows current measurement circuit 800 as having certain components that are arranged in a certain manner, current measurement circuit 800 may include additional or fewer components that are arranged differently.

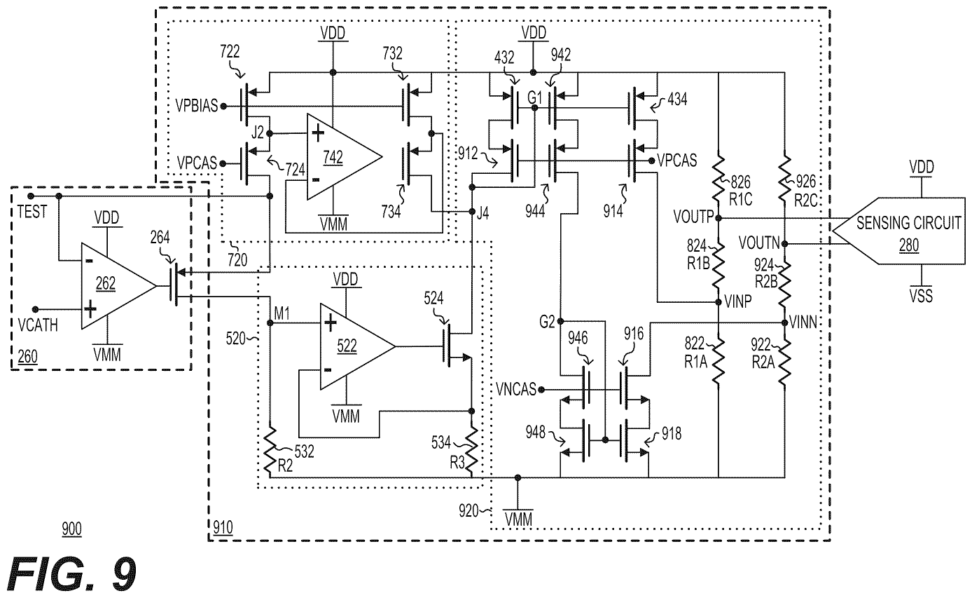

FIG. 9 shows a current measurement circuit 900 with an improved level translation and scaling circuit 910 in accordance with one example. In this current measurement circuit, the sensing circuit 280 is configured to interface with a differential voltage output by the level translation and scaling circuit 910. As explained earlier, one implementation of sensing circuit 280 relates to an analog to digital converter (ADC). The improvement to the level translation and scaling circuit 910 is better common-mode rejection for use with the ADC. In other words, with the improved level translation and scaling circuit 910, the ADC responds only to the differential voltage signals and not to any changes in the common-mode input voltages. Unless expressly indicated otherwise, the same or similar circuits and components that are shown in FIG. 9 are referred to using the same or similar reference numbers as used in FIG. 2, FIG. 3, FIG. 4, FIG. 5, FIG. 6, FIG. 7, or FIG. 8. As a result, such same or similar circuits and components are not described again as part of the description associated with FIG. 9. Level translation and scaling circuit 910 includes cascoded current mirrors and resistor strings to scale and create input and output common-mode voltage levels, in combination with the other components of current measurement circuit 900. Level translation and scaling circuit 910 includes PMOS transistor 912, which is arranged between node G1 and a terminal of PMOS transistor 432, as shown in FIG. 9. Another PMOS transistor 914 is added, with its gate coupled to the gate of PMOS transistor 912. One terminal of the PMOS transistor 914 is coupled with a terminal of PMOS transistor 434 and another terminal of PMOS transistor 914 is coupled to the positive input voltage (VINP) terminal. In addition, PMOS transistors 942 and 944 are added between the node G1 and node G2, creating a cascoded current mirror. Another cascoded current mirror is formed by arranging NOS transistors 916, 918, 946, and 948, as shown in FIG. 9. One of the terminals of transistor 916 is coupled to the negative input voltage (VINN) terminal.

With continued reference to FIG. 9, the voltages received at the positive input voltage (VINP) terminal and the negative input voltage (VINN) terminal are scaled using resistor strings prior to the differential voltage being sensed by the sensing circuit 280, which can be implemented as an ADC. Resistor strings include a first resistor string comprising a resistor R1A 822, which is coupled between the VMM voltage terminal and the VINP voltage terminal. The first resistor string further includes a second resistor R1B 824, which is coupled between the VINP voltage terminal and the positive output (VOUTP) voltage terminal. The first resistor string further includes a third resistor R1C 826, which is coupled between the VOUTP voltage terminal and the VDD voltage terminal. Resistor strings further include a second resistor string comprising a resistor R2A 922, which is coupled between the VMM voltage terminal and the VINN voltage terminal. The second resistor string further includes a second resistor R2B 924, which is coupled between the VINN voltage terminal and the negative output (VOUTN) voltage terminal. The second resistor string further includes a third resistor R2C 926, which is coupled between the VOUTN voltage terminal and the VDD voltage terminal.

The combination of the two resistor strings creates a differential voltage with respect to the common-mode voltage levels established by the resistor strings. Advantageously, this differential voltage when supplied as an input to the ADC (included in sensing circuit 280) improves the performance of the current measurement circuit 900 since the ADC responds only to the differential voltage signals and not to any changes in the common-mode input voltages. Although FIG. 9 shows current measurement circuit 900 as having certain components that are arranged in a certain manner, current measurement circuit 900 may include additional or fewer components that are arranged differently.

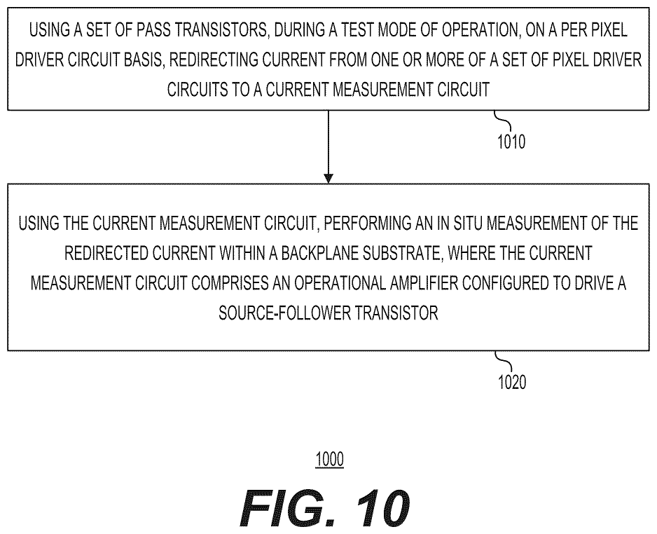

FIG. 10 shows a flow chart 1000 of an example method for in situ measurement of the current associated with one or more micro-LEDs in a micro-LED system. In one example, the micro-LED system corresponds to the micro-LED systems described earlier with respect to FIG. 1 and FIG. 2. As described earlier, the micro-LED system can include: (1) a set of micro-LEDs formed in a display substrate, and (2) a set of pixel driver circuits formed in a backplane substrate coupled to the display substrate, where each of the set of pixel driver circuits is to provide a current to a respective one of the set of micro-LEDs during a normal mode of operation for the set of micro-LEDs. Step 1010 includes using a set of pass transistors, during a test mode of operation, on a per pixel driver circuit basis, redirecting current from one or more of the set of pixel driver circuits to a current measurement circuit. As explained earlier, PMOS transistor 238 of FIG. 2 (available on a per-pixel driver circuit basis) can be used as part of a set of pass transistors to allow for the redirection current from one or more of the pixel driver circuits (e.g., one or more of pixel driver circuits 230 of FIG. 2) to a current measurement circuit (e.g., current measurement circuit 250 of FIG. 2). As shown in view 110 of FIG. 1, a micro-LED array with micro-LEDs (e.g., micro-LEDs 132 and 134) is organized in rows (e.g., rows 112, 114, and 116) and columns (e.g., columns 122, 134, and 126). As shown in view 150 of backplane substrate 104, the backplane substrate 104 includes an array of pixel hardware blocks (e.g., pixel hardware blocks 172 and 174) that are also organized in rows (e.g., rows 152, 154, and 156) and columns (e.g., columns 162, 164, and 166). As described earlier with respect to FIG. 2, the select signal—TSEL—can be used to select an individual micro-LED pixel driver circuit (e.g., by column and row) or in combination with other micro-LEDs' pixel driver circuits.

Step 1020 includes using the current measurement circuit performing an in situ measurement of the redirected current within the backplane substrate, where the current measurement circuit comprises an operational amplifier configured to drive a source-follower transistor. Any of the current measurement circuits described earlier can be used to perform this step. As an example, current measurement circuit 250 of FIG. 2 can be used to perform the current measurement. The current measurement circuit included other components, such as the level translation and scaling circuit and the sensing circuit described earlier. Additional details and improvements to the level translation and scaling circuit (e.g., level translation and scaling circuit 270 of FIG. 2) are described with respect to FIGS. 4-9.

In conclusion, the present disclosure relates to a micro-LED system including a set of micro-LEDs formed in a display substrate. The micro-LED system may further include a set of pixel driver circuits formed in a backplane substrate coupled to the display substrate, where a respective pixel driver circuit is to provide current to a respective micro-LED during a first mode of operation for the set of micro-LEDs.

The micro-LED system may further include a current measurement circuit, formed in the backplane substrate, comprising an operational amplifier configured to drive a source-follower transistor. The micro-LED system may further include a set of pass transistors to, during a second mode of operation, different from the first mode of operation, on a per pixel driver circuit basis, selectively redirect current from one or more of the set of pixel driver circuits to the current measurement circuit allowing for in situ measurement of the redirected current within the backplane substrate.

The current measurement circuit may further comprise a level translation and scaling circuit coupled to the source-follower transistor and a sensing circuit coupled to the level translation and scaling circuit, where the level translation and scaling circuit is configured to scale voltage levels for coupling with the sensing circuit. The level translation and scaling circuit may comprise two current mirror circuits and at least one resistor. The channel length and the channel width of respective transistors used to form the two current mirror circuits may be ratioed to scale the redirected current.

The level translation and scaling circuit may comprise a current mirror circuit and a current repeater circuit, where the current repeater circuit includes a second operational amplifier and two resistors arranged to improve an input common-mode voltage of the level translation and scaling circuit. The level translation and scaling circuit may comprise at least one current source for providing current to the source-follower transistor during the in situ measurement of the redirected current.

The micro-LED system may further comprise a gain-boosted cascode current circuit for implementing the at least one current source. The level translation and scaling circuit may further comprise cascoded current mirrors and resistor strings to scale common-mode input voltage and common-mode output voltage. The cascoded current mirrors and the resistor strings may further be configured to improve the swing of a differential voltage output by the level scaling and translation circuit.

In another example, the present disclosure relates to a method for in situ measurement of current associated with one or more micro-LEDs in a micro-LED system. The micro-LED system may include: (1) a set of micro-LEDs formed in a display substrate, and (2) a set of pixel driver circuits formed in a backplane substrate coupled to the display substrate, where each of the set of pixel driver circuits is to provide current to a respective one of the set of micro-LEDs during a normal mode of operation for the set of micro-LEDs.

The method may include using a set of pass transistors, during a test mode of operation, on a per pixel driver circuit basis, redirecting current from one or more of the set of pixel driver circuits to a current measurement circuit. The method may further include using the current measurement circuit performing an in situ measurement of the redirected current within the backplane substrate, where the current measurement circuit comprises an operational amplifier configured to drive a source-follower transistor.

The current measurement circuit may further comprise a level translation and scaling circuit coupled to the source-follower transistor and a sensing circuit coupled to the level translation and scaling circuit. The method may further comprise, using the level translation and scaling circuit scaling voltage levels for coupling with the sensing circuit. The level translation and scaling circuit may comprise two current mirror circuits and at least one resistor. The channel length and the channel width of respective transistors used to form the two current mirror circuits may be ratioed to scale the redirected current.

The level translation and scaling circuit may comprise a current mirror circuit and a current repeater circuit, where the current repeater circuit includes a second operational amplifier and two resistors arranged to improve an input common-mode voltage of the level translation and scaling circuit. The level translation and scaling circuit may comprise at least one current source for providing current to the source-follower transistor during the in situ measurement of the redirected current.

In yet another example, the present disclosure relates to a micro-LED system comprising a set of micro-LEDs formed in a display substrate. The micro-LED system may further include a set of pixel driver circuits formed in a backplane substrate coupled to the display substrate, where a respective pixel driver circuit is to provide current to a respective micro-LED during a first mode of operation for the set of micro-LEDs.

The micro-LED system may further include a set of pass transistors to, during a second mode of operation, different from the first mode of operation, on a per pixel driver circuit basis, selectively redirect current from one or more of the set of pixel driver circuits to a current measurement circuit, formed in the backplane substrate, allowing for in situ measurement of the redirected current within the backplane substrate. The current measurement circuit may comprise: (1) an operational amplifier configured to drive a source-follower transistor, (2) a level translation and scaling circuit coupled to the source-follower transistor, and (3) an analog to digital converter (ADC) coupled to the level translation and scaling circuit, where the level translation and scaling circuit is configured to scale voltage levels for coupling with the ADC.

The current measurement circuit may further comprise a circuit to add current to one or more of the micro-LEDs under test to distinguish between a first condition related to a short in a micro-LED and a second condition related to an open in a corresponding pixel driver circuit. The current measurement circuit may further comprise a circuit to subtract current from one or more of the micro-LEDs under test to cancel any leakage current flowing through the one or more of the micro-LEDs under test.

The level translation and scaling circuit may comprise two current mirror circuits and at least one resistor. The channel length and the channel width of respective transistors used to form the two current mirror circuits may be ratioed to scale the redirected current. The level translation and scaling circuit may comprise a current mirror circuit and a current repeater circuit, where the current repeater circuit includes a second operational amplifier and two resistors arranged to improve an input common-mode voltage of the level translation and scaling circuit.

The level translation and scaling circuit may comprise at least one current source for providing current to the source-follower transistor during the in situ measurement of the redirected current. The level translation and scaling circuit may further comprise cascoded current mirrors and resistor strings to scale common-mode input voltage and common-mode output voltage. The cascoded current mirrors and the resistor strings may further be configured to improve swing of a differential voltage output by the level scaling and translation circuit.

It is to be understood that the methods, modules, and components depicted herein are merely exemplary. Alternatively, or in addition, the functionality described herein can be performed, at least in part, by one or more hardware logic components. For example, and without limitation, illustrative types of hardware logic components that can be used include Field-Programmable Gate Arrays (FPGAs), Application-Specific Integrated Circuits (ASICs), Application-Specific Standard Products (ASSPs), System-on-a-Chip systems (SOCs), or Complex Programmable Logic Devices (CPLDs). In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or inter-medial components. Likewise, any two components so associated can also be viewed as being “operably connected,” or “coupled,” to each other to achieve the desired functionality.

The functionality associated with some examples described in this disclosure can also include instructions stored in a non-transitory media. The term “non-transitory media” as used herein refers to any media storing data and/or instructions that cause a machine to operate in a specific manner. Exemplary non-transitory media include non-volatile media and/or volatile media. Non-volatile media include, for example, a hard disk, a solid state drive, a magnetic disk or tape, an optical disk or tape, a flash memory, an EPROM, NVRAM, PRAM, or other such media, or networked versions of such media. Volatile media include, for example, dynamic memory, such as, DRAM, SRAM, a cache, or other such media. Non-transitory media is distinct from, but can be used in conjunction with transmission media. Transmission media is used for transferring data and/or instruction to or from a machine. Exemplary transmission media, include coaxial cables, fiber-optic cables, copper wires, and wireless media, such as radio waves.

Furthermore, those skilled in the art will recognize that boundaries between the functionality of the above described operations are merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Although the disclosure provides specific examples, various modifications and changes can be made without departing from the scope of the disclosure as set forth in the claims below. Accordingly, the specification and figures are to be regarded in an illustrative rather than a restrictive sense, and all such modifications are intended to be included within the scope of the present disclosure. Any benefits, advantages, or solutions to problems that are described herein with regard to a specific example are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed:

1. A micro-LED system comprising:
a set of micro-LEDs formed in a display substrate;
a set of pixel driver circuits formed in a backplane substrate coupled to the display substrate, wherein a respective pixel driver circuit is to provide current to a respective micro-LED during a first mode of operation for the set of micro-LEDs;
a current measurement circuit, formed in the backplane substrate, comprising an operational amplifier configured to drive a source-follower transistor; and
a set of pass transistors to, during a second mode of operation, different from the first mode of operation, on a per pixel driver circuit basis, selectively redirect current from one or more of the set of pixel driver circuits to the current measurement circuit allowing for in situ measurement of the redirected current within the backplane substrate.

2. The micro-LED system of claim 1, wherein the current measurement circuit further comprises a level translation and scaling circuit coupled to the source-follower transistor and a sensing circuit coupled to the level translation and scaling circuit, wherein the level translation and scaling circuit is configured to scale voltage levels for coupling with the sensing circuit.

3. The micro-LED system of claim 2, wherein the level translation and scaling circuit comprises two current mirror circuits and at least one resistor, and wherein a channel length and a channel width of respective transistors used to form the two current mirror circuits are ratioed to scale the redirected current.

4. The micro-LED system of claim 2, wherein the level translation and scaling circuit comprises a current mirror circuit and a current repeater circuit, wherein the current repeater circuit includes a second operational amplifier and two resistors arranged to improve an input common-mode voltage of the level translation and scaling circuit.

5. The micro-LED system of claim 2, wherein the level translation and scaling circuit comprises at least one current source for providing current to the source-follower transistor during the in situ measurement of the redirected current.

6. The micro-LED system of claim 3, further comprising a gain-boosted cascode current circuit for implementing the at least one current source.

7. The micro-LED system of claim 2, wherein the level translation and scaling circuit further comprises cascoded current mirrors and resistor strings to scale common-mode input voltage and common-mode output voltage.

8. The micro-LED system of claim 6, wherein the cascoded current mirrors and the resistor strings are further configured to improve swing of a differential voltage output by the level scaling and translation circuit.

9. A method for in situ measurement of current associated with one or more micro-LEDs in a micro-LED system comprising: (1) a set of micro-LEDs formed in a display substrate, and (2) a set of pixel driver circuits formed in a backplane substrate coupled to the display substrate, wherein each of the set of pixel driver circuits is to provide current to a respective one of the set of micro-LEDs during a normal mode of operation for the set of micro-LEDs, the method comprising:
using a set of pass transistors, during a test mode of operation, on a per pixel driver circuit basis, redirecting current from one or more of the set of pixel driver circuits to a current measurement circuit; and
using the current measurement circuit, performing an in situ measurement of the redirected current within the backplane substrate, wherein the current measurement circuit comprises an operational amplifier configured to drive a source-follower transistor.

10. The method of claim 9, wherein the current measurement circuit further comprises a level translation and scaling circuit coupled to the source-follower transistor and a sensing circuit coupled to the level translation and scaling circuit, and wherein the method further comprises, using the level translation and scaling circuit scaling voltage levels for coupling with the sensing circuit.

11. The method of claim 10, wherein the level translation and scaling circuit comprises two current mirror circuits and at least one resistor, and wherein a channel length and a channel width of respective transistors used to form the two current mirror circuits are ratioed to scale the redirected current.

12. The method of claim 10, wherein the level translation and scaling circuit comprises a current mirror circuit and a current repeater circuit, wherein the current repeater circuit includes a second operational amplifier and two resistors arranged to improve an input common-mode voltage of the level translation and scaling circuit.

13. The method of claim 10, wherein the level translation and scaling circuit comprises at least one current source for providing current to the source-follower transistor during the in situ measurement of the redirected current.

14. A micro-LED system comprising:
a set of micro-LEDs formed in a display substrate;
a set of pixel driver circuits formed in a backplane substrate coupled to the display substrate, wherein a respective pixel driver circuit is to provide current to a respective micro-LED during a first mode of operation for the set of micro-LEDs;
a set of pass transistors to, during a second mode of operation, different from the first mode of operation, on a per pixel driver circuit basis, selectively redirect current from one or more of the set of pixel driver circuits to a current measurement circuit, formed in the backplane substrate, allowing for in situ measurement of the redirected current within the backplane substrate; and
wherein the current measurement circuit comprises: (1) an operational amplifier configured to drive a source-follower transistor, (2) a level translation and scaling circuit coupled to the source-follower transistor, and (3) an analog to digital converter (ADC) coupled to the level translation and scaling circuit, wherein the level translation and scaling circuit is configured to scale voltage levels for coupling with the ADC.

15. The micro-LED system of claim 14, wherein the current measurement circuit further comprises a circuit to add current to one or more of the micro-LEDs under test to distinguish between a first condition related to a short in a micro-LED and a second condition related to an open in a corresponding pixel driver circuit.

16. The micro-LED system of claim 14, wherein the current measurement circuit further comprises a circuit to subtract current from one or more of the micro-LEDs under test to cancel any leakage current flowing through the one or more of the micro-LEDs under test.

17. The micro-LED system of claim 14, wherein the level translation and scaling circuit comprises two current mirror circuits and at least one resistor, and wherein a channel length and a channel width of respective transistors used to form the two current mirror circuits are ratioed to scale the redirected current.

18. The micro-LED system of claim 14, wherein the level translation and scaling circuit comprises a current mirror circuit and a current repeater circuit, wherein the current repeater circuit includes a second operational amplifier and two resistors arranged to improve an input common-mode voltage of the level translation and scaling circuit.

19. The micro-LED system of claim 14, wherein the level translation and scaling circuit comprises at least one current source for providing current to the source-follower transistor during the in situ measurement of the redirected current.

20. The micro-LED system of claim 14, wherein the level translation and scaling circuit further comprises cascoded current mirrors and resistor strings to scale common-mode input voltage and common-mode output voltage, and wherein the cascoded current mirrors and the resistor strings are further configured to improve swing of a differential voltage output by the level scaling and translation circuit.
